(19) United States
(12) Patent Application Publication
(10) Pub. No.: US 2026/0068483 A1
(43) Pub. Date: Mar. 5, 2026

(54) DISPLAY DEVICE

(71) Applicant: Sharp Display Technology Corporation, Kameyama City, Mie S (JP)

(72) Inventors: Tadayoshi MIYAMOTO, Kameyama City, Mie (JP); Yoshinobu NAKAMURA, Kameyama City, Mie (JP); Toshihiro KANEKO, Kameyama City, Mie (JP)

(21) Appl. No.: 19/104,202

(22) PCT Filed: Sep. 5, 2022
(86) PCT No.: PCT/JP2022/033220

§ 371 Date: Feb. 14, 2025

(51) Int. Cl. H10K 59/80

(52) U.S. Cl. CPC H10K 59/80524; H10K 59/80518; H10K 59/871

(57) ABSTRACT

A TFT layer is provided on a base substrate, a light-emitting element layer is provided on the TFT layer, a plurality of first electrodes, a first edge cover commonly provided, a plurality of third electrodes, a plurality of light-emitting function layers, and a second electrode commonly provided are layered in order in the light-emitting element layer, corresponding to a plurality of subpixels constituting a display region, each first electrode exposed from the first edge cover is provided with a first recessed portion, and a surface of each third electrode is provided with a second recessed portion corresponding to the first recessed portion.

### TECHNICAL FIELD

The present invention relates to a display device.

### BACKGROUND ART

In recent years, as a display device replacing a liquid crystal display device, a self-luminous organic electroluminescence (hereinafter also referred to as “EL”) display device using an organic EL element has attracted attention. The organic EL display device includes, for example, a base substrate, a Thin Film Transistor (hereinafter, also referred to as a “TFT”) layer provided on the base substrate, an organic EL element layer provided on the TFT layer, and a sealing film provided on the organic EL element layer. Here, an organic EL element includes a first electrode provided on the TFT layer, an organic EL layer provided as a light-emitting function layer on the first electrode, and a second electrode provided on the organic EL layer.

For example, PTL 1 describes that a protruding portion is formed on a surface of a first electrode due to a protruding portion on a surface of a passivation film, thereby reflecting light generated from a light-emitting element layer to improve luminous efficiency.

### CITATION LIST

### Patent Literature

PTL 1: US 2017/0125740 A

### SUMMARY OF INVENTION

### Technical Problem

Now, in the organic EL display device, for example, when the organic EL layer is formed on the first electrode by using a solution coating device such as an ink-jet or various coaters, solute components are likely to aggregate at the edge of an applied film due to a coffee ring effect in drying the applied film to be the organic EL layer. This makes a film thickness of the organic EL layer on a central portion of the first electrode relatively thinner, and makes a film thickness of the organic EL layer on an edge portion of the first electrode relatively thicker. In this case, since the film thickness of the organic EL layer varies in a subpixel, luminous unevenness occurs, thereby decreasing the luminous efficiency. Thus, there is room for improvement.

The present invention has been made in view of the above, and an object thereof is to suppress a variation in film thickness of a light-emitting function layer in a subpixel.

### Solution to Problem

In order to achieve the object, according to the present invention, there is provided a display device including a base substrate, a thin film transistor layer provided on the base substrate, and a light-emitting element layer provided on the thin film transistor layer, the light-emitting element layer being obtained by layering a plurality of first electrodes, a first edge cover commonly provided, a plurality of light-emitting function layers, and a second electrode commonly provided in order corresponding to a plurality of subpixels constituting a display region, wherein the first edge cover covers a peripheral edge portion of each of the plurality of first electrodes, a plurality of third electrodes are provided between the first edge cover and the plurality of light-emitting function layers, and correspond to the plurality of subpixels, each of the plurality of first electrodes exposed from the first edge cover is provided with a first recessed portion opened toward a side of the corresponding third electrode of the plurality of third electrodes, and a surface of each of the plurality of third electrodes is provided with a second recessed portion corresponding to the first recessed portion.

### Advantageous Effects of Invention

According to the present invention, it is possible to suppress a variation in film thickness of the light-emitting function layer in each subpixel.

### BRIEF DESCRIPTION OF DRAWINGS

FIG. 1 is a plan view illustrating a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is a plan view of a first electrode exposed from a first edge cover constituting the organic EL display device according to the first embodiment of the present invention.

FIG. 5 is an equivalent circuit diagram of a TFT layer constituting the organic EL display device according to the first embodiment of the present invention.

FIG. 6 is a cross-sectional view of an organic EL layer constituting the organic EL display device according to the first embodiment of the present invention.

FIG. 7 is a plan view of a modified example of the first electrode exposed from the first edge cover constituting the organic EL display device according to the first embodiment of the present invention.

FIG. 8 is a plan view of a first electrode exposed from a first edge cover constituting an organic EL display device according to a second embodiment of the present invention.

FIG. 9 is a plan view of a first modified example of the first electrode exposed from the first edge cover constituting the organic EL display device according to the second embodiment of the present invention.

FIG. 10 is a plan view of a second modified example of the first electrode exposed from the first edge cover constituting the organic EL display device according to the second embodiment of the present invention.

FIG. 11 is a plan view of a first electrode exposed from a first edge cover constituting an organic EL display device according to a third embodiment of the present invention.

### DESCRIPTION OF EMBODIMENTS

Embodiments of a technique according to the present invention will be described below in detail with reference to the drawings. Note that the technique according to the present invention is not limited to the embodiments to be described below.

### First Embodiment

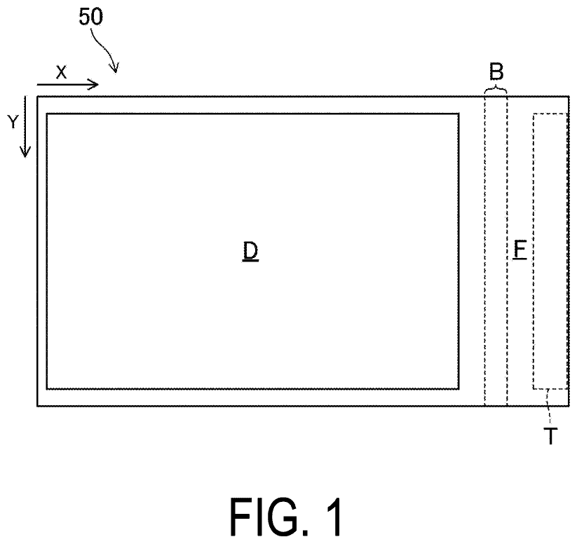

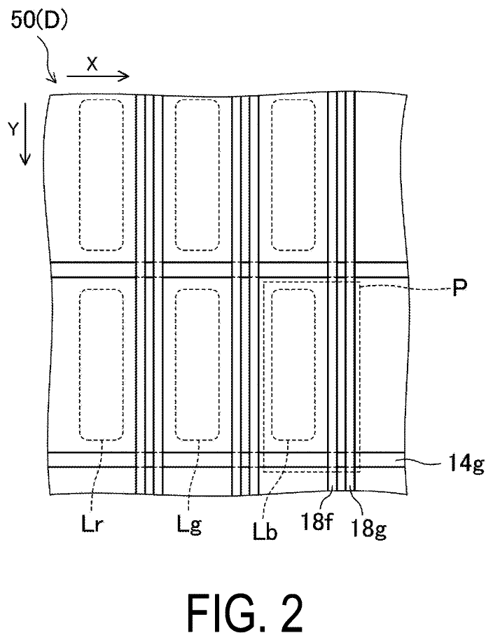

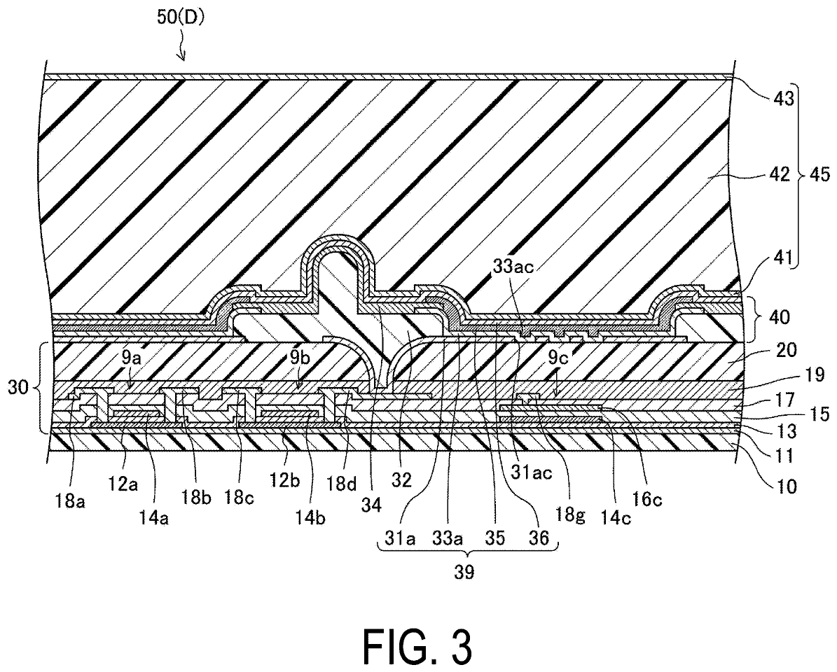

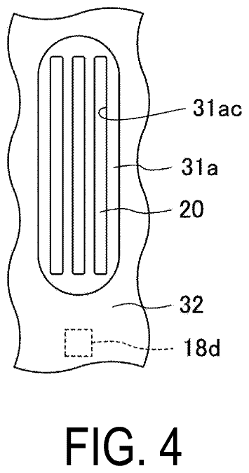

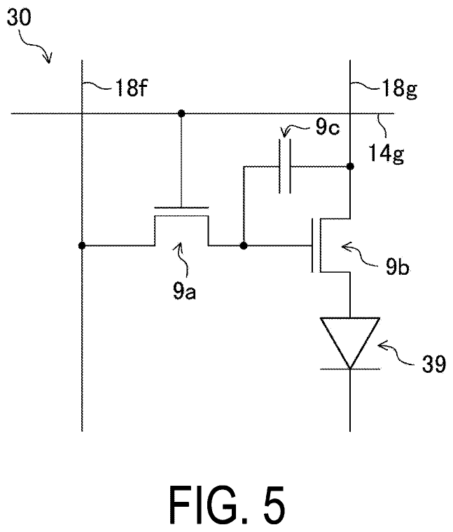

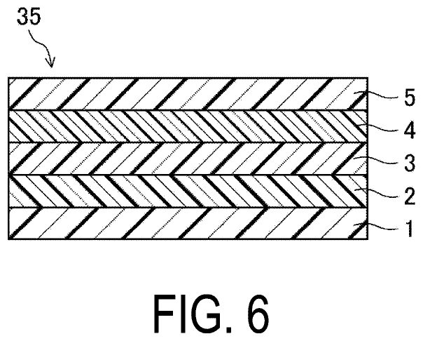

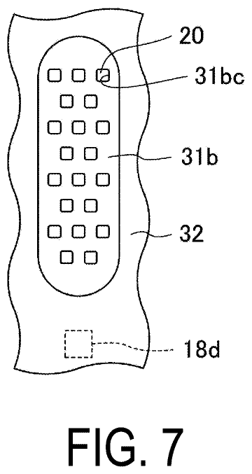

FIG. 1 to FIG. 7 illustrate a display device according to a first embodiment of the present invention. Note that, in each of the following embodiments, an organic EL display device including an organic EL element layer is exemplified as a display device including a light-emitting element layer. Here, FIG. 1 is a plan view illustrating a schematic configuration of an organic EL display device 50 according to the present embodiment. FIG. 2 and FIG. 3 are a plan view and a cross-sectional view, respectively, of a display region D in the organic EL display device 50. Further, FIG. 4 is a plan view of a first electrode 31a exposed from a first edge cover 32 constituting the organic EL display device 50. Further, FIG. 5 is an equivalent circuit diagram of a TFT layer 30 constituting the organic EL display device 50. Further, FIG. 6 is a cross-sectional view of an organic EL layer 35 constituting the organic EL display device 50. Further, FIG. 7 is a plan view of a first electrode 31b according to a modified example of the first electrode 31a exposed from the first edge cover 32.

As illustrated in FIG. 1, the organic EL display device 50 includes, for example, a display region D that is provided in a rectangular shape and displays an image, and a frame region F provided in a frame-like shape surrounding the display region D. Note that, in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

A terminal portion T is provided extending in one direction (Y direction in the drawing) at a right end portion of the frame region F in FIG. 1. As illustrated in FIG. 1, between the display region D and the terminal portion T, that is, in the frame region F, a bending portion B, which is bendable, for example, by 180 degrees (in a U-shape) with the Y direction in the drawing as a bending axis, is provided extending in one direction (Y direction in the drawing) on a display region D side of the terminal portion T.

As illustrated in FIG. 3, the organic EL display device 50 includes a resin substrate 10 provided as a base substrate, the TFT layer 30 provided on the resin substrate 10, an organic EL element layer 40 provided on the TFT layer 30 as a light-emitting element layer, and a sealing film 45 provided on the organic EL element layer 40.

The resin substrate 10 is formed of, for example, a polyimide resin or the like.

As illustrated in FIG. 3, the TFT layer 30 includes a base coat film 11 provided on the resin substrate 10, a plurality of first TFTs 9a, a plurality of second TFTs 9b, and a plurality of capacitors 9c, which are provided on the base coat film 11, and a protective insulating film 19 and a flattening film 20 that are provided in order on each first TFT 9a, each second TFT 9b, and each capacitor 9c. Here, as illustrated in FIG. 2, in the TFT layer 30, a plurality of gate lines 14g are provided to extend parallel to each other in an X direction in the figure. Additionally, as illustrated in FIG. 2, in the TFT layer 30, a plurality of source lines 18f are provided extending in a direction intersecting (orthogonal to) the plurality of gate lines 14g, that is, parallel to each other in the Y direction in the drawing. In addition, as illustrated in FIG. 2, in the TFT layer 30, a plurality of power source lines 18g are provided to extend parallel to each other in the Y direction in the figure. Then, as illustrated in FIG. 2, each of the power source lines 18g is provided to be adjacent to each of the source lines 18f. Further, as illustrated in FIG. 4, in the TFT layer 30, each of the subpixels P includes a first TFT 9a, a second TFT 9b, and a capacitor 9c. Note that in the TFT layer 30, as illustrated in FIG. 3, on the resin substrate 10, the base coat film 11, a semiconductor film to serve as a semiconductor layer 12a and the like, which will be described later, a gate insulating film 13, a first metal film to serve as the gate line 14g and the like, a first interlayer insulating film 15, a second metal film to serve as an upper conductive layer 16c and the like, which will be described later, a second interlayer insulating film 17, a third metal film to serve as the source line 18f, the power source line 18g, and the like, the protective insulating film 19, and the flattening film 20 are sequentially layered.

Each of the base coat film 11, the gate insulating film 13, the first interlayer insulating film 15, the second interlayer insulating film 17, and the protective insulating film 19 is constituted by, for example, an inorganic insulating film that is a single-layer film or a layered film of silicon nitride, silicon oxide, silicon oxynitride, or the like.

The first TFT 9a is electrically connected to the corresponding gate line 14g and source line 18f in each of the subpixels P, as illustrated in FIG. 5. Here, as illustrated in FIG. 3, the first TFT 9a includes the semiconductor layer 12a provided on the base coat film 11, a gate electrode 14a provided on the semiconductor layer 12a with the gate insulating film 13 interposed therebetween, and a source electrode 18a and a drain electrode 18b that are provided on the second interlayer insulating film 17 so as to be separated from each other.

The semiconductor layer 12a is formed of, for example, a semiconductor film made of polysilicon such as Low Temperature Poly Silicon (LTPS), and includes a source region and a drain region that are defined so as to be separated from each other, and a channel region defined between the source region and the drain region.

The gate electrode 14a is provided overlapping with the channel region of the first semiconductor layer 12a, and is configured to control conduction between the source region and the drain region of the first semiconductor layer 12a. Here, similarly to the gate line 14g and the like, the gate electrode 14a is formed of a first metal film.

Further, as illustrated in FIG. 3, the source electrode 18a and the drain electrode 18b are electrically connected to the source region and the drain region of the semiconductor layer 12a, respectively, through respective contact holes formed at the gate insulating film 13, the first interlayer insulating film 15, and the second interlayer insulating film 17. Here, similarly to the source line 18f and the power source line 18g, the source electrode 18a and the drain electrode 18b are formed of a third metal film.

The second TFT 9b is electrically connected to the corresponding first TFT 9a and power source line 18g in each of the subpixels P as illustrated in FIG. 5. Here, as illustrated in FIG. 3, the second TFT 9b includes a semiconductor layer 12b provided on the base coat film 11, a gate electrode 14b provided on the semiconductor layer 12b with the gate insulating film 13 interposed therebetween, and a source electrode 18c and a drain electrode 18d that are provided on the second interlayer insulating film 17 so as to be separated from each other.

Similarly to the semiconductor layer 12a, the semiconductor layer 12b is formed of a semiconductor film made of, for example, polysilicon such as LTPS, and includes a source region and a drain region that are defined so as to be separated from each other, and a channel region defined between the source region and the drain region.

The gate electrode 14b is provided overlapping with the channel region of the semiconductor layer 12b, and is configured to control conduction between the source region and the drain region of the first semiconductor layer 12b. Here, similarly to the gate line 14g and the like, the gate electrode 14b is formed of a first metal film.

As illustrated in FIG. 3, the source electrode 18c and the drain electrode 18d are electrically connected to the source region and the drain region of the semiconductor layer 12b, respectively, through respective contact holes formed in the layered film of the gate insulating film 13, the first interlayer insulating film 15, and the second interlayer insulating film 17. Here, similarly to the source line 18f and the power source line 18g, the source electrode 18c and the drain electrode 18d are formed of a third metal film.

Note that in the present embodiment, the semiconductor layers 12a and 12b formed of a semiconductor film made of polysilicon have been exemplified, but the semiconductor layers 12a and 12b may be formed of a semiconductor film made of an oxide semiconductor such as an In—Ga—Zn—O-based semiconductor. Furthermore, the TFT layer 30 may have a hybrid structure in which a TFT including a semiconductor layer formed of polysilicon and a TFT including a semiconductor layer formed of an oxide semiconductor are provided.

The capacitor 9c is electrically connected to the corresponding first TFT 9a and power source line 18g in each of the subpixels P as illustrated in FIG. 5. Here, as illustrated in FIG. 3, the capacitor 9c includes a lower conductive layer 14c formed of a first metal film, an upper conductive layer 16c provided and formed of a second metal film, and the first interlayer insulating film 15 provided between the lower conductive layer 14c and the upper conductive layer 16c. Note that, as illustrated in FIG. 3, the upper conductive layer 16c is electrically connected to the power source line 18g via contact holes formed in the second interlayer insulating film 17.

The flattening film 20 includes a flat surface in the display region D, and is formed of an organic resin material such as a polyimide resin, for example.

As illustrated in FIG. 3, the organic EL element layer 40 includes a plurality of first electrodes 31a, a first edge cover 32 commonly provided, a plurality of third electrodes 33a, a second edge cover 34 commonly provided, a plurality of organic EL layers 35, and a second electrode 36 commonly provided, which are sequentially layered, corresponding to the plurality of subpixels P. Here, in each of the subpixels P, the first electrode 31a, the third electrode 33a, the organic EL layer 35, and the second electrode 36 constitute an organic EL element 39, and in the organic EL element layer 40, a plurality of organic EL elements 39 provided corresponding to the plurality of subpixels P are disposed in a matrix shape.

As illustrated in FIG. 3, the first electrode 31a is electrically connected to the drain electrode 18d of the second TFT 9b of each subpixel P through a contact hole formed at the protective insulating film 19 and the flattening film 20. Here, the first electrode 31a is formed of, for example, a transparent conductive film such as Indium-Tin-Oxide (hereinafter, also referred to as “ITO”) and have optical transparency. Further, as will be described later, a peripheral edge portion of the first electrode 31a is covered with the first edge cover 32, and the first electrode 31a exposed from the first edge cover 32, as illustrated in FIG. 3 in a cross-sectional view, is provided with a plurality of first recessed portions 31ac extending through the first electrode 31a and exposing the flattening film 20 of the TFT layer 30. In addition, the plurality of first recessed portions 31ac extend in parallel to each other and have linear shapes, as illustrated in FIG. 4 in a plan view. Note that in the present embodiment, the first recessed portions 31ac provided so as to extend through the first electrode 31a have been exemplified, but the first recessed portions 31ac may be provided so as to be opened to a third electrode 33a side without extending through the first electrode 31a. In addition, in the present embodiment, the first electrode 31a in which the plurality of first recessed portions 31ac are provided in the linear shapes have been exemplified, but instead of the first electrode 31a, as illustrated in FIG. 7, the first electrode 31b may be provided with a plurality of first recessed portions 31bc separated from each other in dot shapes.

The first edge cover 32 is provided in a lattice pattern over the entire display region D, and covers a peripheral edge portion of the first electrode 31a as illustrated in FIG. 3. Here, the first edge cover 32 is made of, for example, an organic resin material such as a polyimide resin or an acrylic resin, a polysiloxane-based Spin-On-Glass (SOG) material, or the like.

The third electrode 33a has a function to inject a hole (positive hole) into the organic EL layer 35. Additionally, the third electrode 33a is preferably made of a material having a high work function to improve hole injection efficiency into the organic EL layer 35. Here, the third electrode 33a is formed of, for example, a layered film in which a transparent conductive film made of ITO or the like, a metal film made of silver (Ag) or the like, and a transparent conductive film made of ITO or the like are layered in order, and has light reflectivity. Additionally, as illustrated in FIG. 3, a surface of the third electrode 33a is provided with a plurality of second recessed portions 33ac corresponding to the plurality of first recessed portions 31ac of the first electrode 31a.

The second edge cover 34 is provided in a lattice pattern over the entire display region D, and covers a peripheral edge portion of the third electrode 33a, as illustrated in FIG. 3. Here, the second edge cover 34 is constituted by an inorganic insulating film that is a single-layer film or a layered film of silicon nitride, silicon oxide, silicon oxynitride, or the like, for example.

The organic EL layer 35 is provided as a light-emitting function layer and includes a hole injection layer 1, a hole transport layer 2, a light-emitting layer 3, an electron transport layer 4, and an electron injection layer 5 that are sequentially layered on the third electrode 33a, as illustrated in FIG. 6. Here, the hole injection layer 1, the hole transport layer 2, the light-emitting layer 3, the electron transport layer 4, and the electron injection layer 5 are formed by applying and drying an aqueous solution in which each of constituent materials is dissolved, as will be described later.

The hole injection layer 1 is also referred to as an anode electrode buffer layer, and has a function to reduce an energy level difference between the third electrode 33a and the organic EL layer 35 and to improve hole injection efficiency from the third electrode 33a to the organic EL layer 35. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function to improve hole transport efficiency from the third electrode 33a to the organic EL layer 35. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where, when a voltage is applied by the third electrode 33a and the second electrode 36, a hole and an electron are injected from the third electrode 33a and the second electrode 36, respectively, and the hole and the electron are recombined. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 36 and the organic EL layer 35 to thereby improve the efficiency of electron injection into the organic EL layer 35 from the second electrode 36, and this function allows the drive voltage of the organic EL element 39 to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 36 is provided covering each of the organic EL layer 35 and the second edge cover 34. Further, the second electrode 36 functions to inject electrons into the organic EL layer 35. Further, the second electrode 36 is preferably made of a material having a low work function to improve the efficiency of electron injection into the organic EL layer 35. Here, the second electrode 36 is formed of, for example, a transparent conductive film such as ITO, and has high optical transparency.

Note that in the present embodiment, although the organic EL element layer 40 of a top-emitting type in which the first electrode 31a and the second electrode 36 have optical transparency and the third electrode 33a has light reflectivity has been exemplified, the organic EL element layer 40 may be a bottom-emitting type in which the first electrode 31a and the third electrode 33a have optical transparency and the second electrode 36 has light reflectivity.

As illustrated in FIG. 3, the sealing film 45 is provided covering the second electrode 36, includes a first inorganic sealing film 41, an organic sealing film 42, and a second inorganic sealing film 43 that are sequentially layered on the second electrode 36, and has a function to protect the organic EL layer 35 of the organic EL element 39 from moisture, oxygen, and the like. Here, the first inorganic sealing film 41 and the second inorganic sealing film 43 include, for example, an inorganic insulating film such as a silicon nitride film, a silicon oxide film, and a silicon oxynitride film. Additionally, the organic sealing film 42 is made of, for example, an organic resin material such as an acrylic resin, an epoxy resin, a silicone resin, a polyurea resin, a parylene resin, a polyimide resin, and a polyamide resin.

In the organic EL display device 50 described above, in each of the subpixels P, a gate signal is input to the first TFT 9a through the gate line 14g to turn on the first TFT 9a, a data signal is written in the gate electrode 14b of the second TFT 9b and the capacitor 9c through the source line 18f, and a current from the power source line 18g corresponding to a gate voltage of the second TFT 9b is supplied to the organic EL layer 39, whereby the light-emitting layer 3 of the organic EL layer 35 emits light to display an image. Note that, in the organic EL display device 50, since even when the first TFT 9a is turned off, the gate voltage of the second TFT 9b is held by the capacitor 9c, the light-emitting layer 3 is kept emitting light until a gate signal of the next frame is input.

Next, a method of manufacturing the organic EL display device 50 according to the present embodiment will be described. Here, the method of manufacturing the organic EL display device 50 according to the present embodiment includes performing TFT layer formation, performing organic EL element layer formation, and performing sealing film formation.

### TFT Layer Formation

First, a silicon nitride film (having a thickness of about 50 nm) and a silicon oxide film (having a thickness of about 250 nm) are sequentially formed on the resin substrate 10 formed on a glass substrate by, for example, plasma Chemical Vapor Deposition (CVD), to form the base coat film 11.

Subsequently, an amorphous silicon film (having a thickness of about 50 nm) is formed, for example, by plasma CVD on the substrate surface on which the base coat film 11 is formed, the amorphous silicon film is crystallized by laser annealing or the like to form the semiconductor film made of polysilicon, and then the semiconductor film is patterned to form the semiconductor layers 12a and 12b, and the like.

After that, a silicon oxide film (having a thickness of about 100 nm) is formed, for example, by plasma CVD on the substrate surface on which the semiconductor layer 12a and the like are formed, to form the gate insulating film 13.

Further, after forming a first metal film such as a molybdenum film (having a thickness of about 200 nm), for example, by sputtering on the substrate surface on which the gate insulating film 13 is formed, the first metal film is patterned to form the gate electrodes 14a and 14b, and the like.

Subsequently, by doping the semiconductor layers 12a and 12b with impurity ions by using the gate electrodes 14a and 14b as a mask, the semiconductor layers 12a and 12b are partially made conductive, and a source region, a drain region, and a channel region are formed in each of the semiconductor layers 12a and 12b.

After that, a silicon nitride film (having a thickness of about 150 nm) and a silicon oxide film (having a thickness of about 100 nm) are sequentially formed, for example, by plasma CVD, on the substrate surface on which the semiconductor layers 12a and 12b are partially made conductive, to form the first interlayer insulating film 15.

Furthermore, after forming a second metal film such as a molybdenum film (having a thickness of approximately 200 nm) or the like by, for example, sputtering on the substrate surface on which the first interlayer insulating film 15 is formed, the second metal film is patterned to form the upper conductive layer 16c and the like.

After that, a silicon oxide film (about 300 nm in thickness) and a silicon nitride film (about 150 nm in thickness) are formed in order, by, for example, plasma CVD, on the substrate surface on which the upper conductive layer 16c and the like are formed, thereby forming the second interlayer insulating film 17.

Subsequently, on the substrate surface on which the second interlayer insulating film 17 is formed, the first gate insulating film 13, the first interlayer insulating film 15, and the second interlayer insulating film 17 are appropriately patterned to form contact holes.

After that, a titanium film (having a thickness of approximately 50 nm), an aluminum film (having a thickness of approximately 400 nm), a titanium film (having a thickness of approximately 100 nm), and the like are sequentially formed, for example, by sputtering, on the substrate surface in which the above-described contact holes are formed to form a third metal film, and then, the third metal film is patterned to form the source electrodes 18a and 18c, the drain electrodes 18b and 18d, and the like.

Further, a silicon oxide film (having a thickness of about 250 nm) is formed on the substrate surface on which the source electrode 18a and the like are formed, for example, by plasma CVD to form the protective insulating film 19.

Subsequently, an acrylic photosensitive resin film (having a thickness of about 2 μm) is applied to the substrate surface on which the protective insulating film 19 is formed, for example, by a spin coating method or a slit coating method, and then, pre-baking, exposing, developing, and post-baking are performed on the applied film to form the flattening film 20 including a contact hole.

Finally, the protective insulating film 19 exposed from the contact hole of the flattening film 20 is removed so that the contact hole reaches the drain electrode 18d of the second TFT 9b.

As described above, the TFT layer 30 can be formed.

### Organic EL Element Layer Formation

First, a transparent conductive film such as an ITO film (having a thickness of about 100 nm) is formed, for example, by sputtering on the substrate surface on which the TFT layer 30 is formed in the TFT layer formation described above, and then the transparent conductive film is patterned to form the first electrode 31a and the like including the first recessed portions 31ac.

Subsequently, an acrylic photosensitive resin film (having a thickness of about 2 μm) is applied to the substrate surface on which the first electrode 31a and the like are formed, for example, by a spin coating method or a slit coating method, and then pre-baking, exposing, developing, and post-baking are performed on the applied film to form the first edge cover 32.

After that, a transparent conductive film such as an ITO film (having a thickness of approximately 40 nm), a metal film such as an Ag film (having a thickness of approximately 20 nm), a transparent conductive film such as an ITO film (having a thickness of approximately 40 nm) are sequentially formed, for example, by sputtering on the substrate surface formed with the first edge cover 32, and then, a layered film thereof is patterned to form the third electrode 33a including the second recessed portion 33ac.

Further, an inorganic insulating film such as a silicon nitride film (having a thickness of about 250 nm) is formed on the substrate surface on which the third electrode 33a and the like are formed, for example, by plasma CVD, and then the inorganic insulating film is patterned to form the second edge cover 34.

Subsequently, the hole injection layer 1, the hole transport layer 2, the light-emitting layer 3, the electron transport layer 4, and the electron injection layer 5 are sequentially formed on the substrate surface on which the second edge cover 34 is formed by repeating application and drying of an aqueous solution in which predetermined constituent materials are dissolved by an ink-jet method, for example, thereby forming the organic EL layer 35.

Finally, on the substrate surface on which the organic EL layer 35 is formed, a transparent conductive film such as an ITO film (having a thickness of about 100 nm) is formed by sputtering by using a mask to form the second electrode 36.

As described above, the organic EL element layer 40 can be formed.

### Sealing Film Formation

First, an inorganic insulating film such as a silicon nitride film, a silicon oxide film, or a silicon oxynitride film is formed by plasma CVD by using a mask on the substrate surface formed with the organic EL element layer 40 in the organic EL element layer formation described above, thereby forming the first inorganic sealing film 41.

Next, on the substrate surface formed with the first inorganic sealing film 41, a film made of an organic resin material such as acrylic resin is formed by, for example, using an ink-jet method to form the organic sealing film 42.

Further, an inorganic insulating film such as a silicon nitride film, a silicon oxide film, or a silicon oxynitride film is formed by plasma CVD on the substrate on which the organic sealing film 42 is formed, by using a mask to form the second inorganic sealing film 43, thereby forming the sealing film 45.

Finally, after a protective sheet (not illustrated) is attached to the substrate surface on which the sealing film 45 is formed, the glass substrate is peeled off from the lower face of the resin substrate 10 by irradiation with laser light from the glass substrate side of the resin substrate 10, and further a protective sheet (not illustrated) is attached to the lower face of the resin substrate 10 from which the glass substrate has been peeled off.

The organic EL display device 50 of the present embodiment can be manufactured in the manner described above.

As described above, according to the organic EL display device 50 of the present embodiment, each first electrode 31a exposed from the first edge cover 32 is provided with the plurality of first recessed portions 31ac extending through the first electrode 31a and exposing the flattening film 20 of the TFT layer 30, and the plurality of first recessed portions 31ac are provided extending in linear shapes. The surface of each third electrode 33a is provided with a plurality of second recessed portions 33ac corresponding to the plurality of first recessed portions 31ac. Here, each of the solute components of the organic EL layer 35, which is formed on the surface of each third electrode 33a by application and drying and which is generally likely to flow to the periphery due to a coffee ring effect, is less likely to flow to the periphery due to an increase in surface area by the plurality of second recessed portions 33ac formed on the surface of each third electrode 33a. This reduces a difference in film thickness of the organic EL layer 35 formed on the surface of each third electrode 33a by application and drying, thereby suppressing a variation in film thickness of the organic EL layer 35 in the subpixel P. Furthermore, since the variation in film thickness of the organic EL layer 35 in each subpixel P can be suppressed, luminous unevenness due to the organic EL element 39 of the subpixel P can be suppressed, which makes it is possible to suppress a decrease in luminous efficiency.

In addition, according to the organic EL display device 50 of the present embodiment, the plurality of second recessed portions 33ac are provided at the surface of the third electrode 33a having light reflectivity, resulting in the improvement of a brightness when the organic EL layer 35 emits light in each subpixel P.

### Second Embodiment

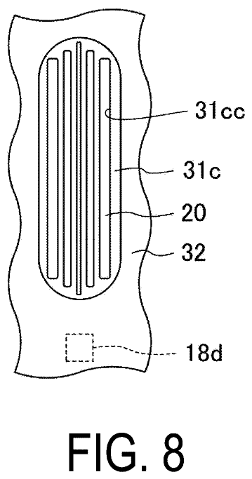

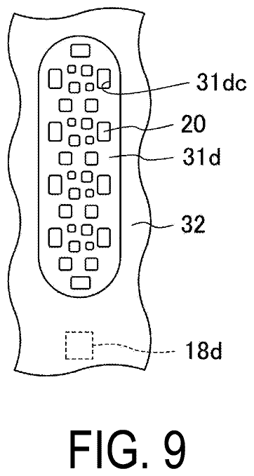

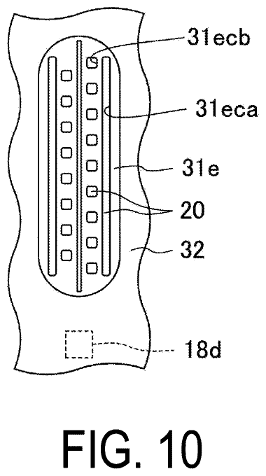

FIG. 8 to FIG. 10 illustrate a display device according to a second embodiment of the present invention. Here, FIG. 8 is a plan view of a first electrode 31c exposed from the first edge cover 32 constituting an organic EL display device of the present embodiment. Further, FIG. 9 is a plan view of a first electrode 31d of a first modified example of the first electrode 31c exposed from the first edge cover 32. Furthermore, FIG. 10 is a plan view of a first electrode 31e of a second modified example of the first electrode 31c exposed from the first edge cover 32. In the following embodiments, parts identical to those in FIG. 1 to FIG. 7 will be denoted by the same reference signs, and a detailed description thereof will be omitted.

In the first embodiment described above, the organic EL display device 50 including the first electrode 31a provided with the plurality of first recessed portions 31ac having the same size as each other has been exemplified, but in the present embodiment, the organic EL display device including the first electrode 31c provided with a plurality of first recessed portions 31cc having different sizes from each other will be exemplified.

The organic EL display device of the present embodiment has substantially the same configuration as that of the organic EL display device 50 except that the first electrode 31c is used instead of the first electrode 31a of the organic EL display device 50 in the first embodiment, and thus the configuration of the first electrode 31c will be mainly described below.

Similarly to the first electrode 31a in the first embodiment, the first electrode 31c is electrically connected to the drain electrode 18d of the second TFT 9b of each of the subpixels P through a contact hole formed in the protective insulating film 19 and the flattening film 20. Further, the first electrode 31c is formed of, for example, a transparent conductive film made of ITO, or the like, and has optical transparency. In addition, a peripheral edge portion of the first electrode 31c is covered with the first edge cover 32, and the first electrode 31c exposed from the first edge cover 32, as illustrated in FIG. 8, is provided with the plurality of first recessed portions 31cc extending through the first electrode 31c and exposing the flattening film 20 of the TFT layer 30. The plurality of first recessed portions 31cc extend in linear shapes in parallel to each other. Here, as illustrated in FIG. 8, line widths of the plurality of first recessed portions 31cc gradually increase from the central portion toward the outside on the inner side of an inner peripheral edge of the first edge cover 32. Further, the surface of the third electrode 33a covering the first electrode 31c is provided with the plurality of second recessed portions 33ac corresponding to the plurality of first recessed portions 31cc of the first electrode 31c.

Note that in the present embodiment, the first electrode 31c in which the plurality of first recessed portions 31cc are provided in the linear shapes has been exemplified, but instead of the first electrode 31c, as illustrated in FIG. 9, a first electrode 31d in which a plurality of first recessed portions 31dc are provided in dot shapes so as to be separated from each other may be used. Here, as illustrated in FIG. 9, areas of the plurality of first recessed portions 31dc gradually increase from the central portion toward the outside on the inner side of the inner peripheral edge of the first edge cover 32.

In addition, in the present embodiment, the first electrode 31c in which the plurality of first recessed portions 31cc are provided in the linear shapes has been exemplified, but instead of the first electrode 31c, as illustrated in FIG. 10, a first electrode 31e in which a plurality of first recessed portions 31eca are provided in linear shapes and a plurality of first recessed portions 31ecb of another type are provided in dot shapes may be provided. Here, as illustrated in FIG. 10, line widths of the plurality of first recessed portions 31eca gradually increase from the central portion toward the outside on the inner side of the inner peripheral edge of the first edge cover 32. Additionally, as illustrated in FIG. 10, the plurality of first recessed portions 31ecb are provided between a pair of first recessed portions 31eca adjacent to each other.

Further, in the present embodiment, and the first modified example and the second modified example thereof, the first recessed portions 31cc, 31dc, and 31eca (31ecb) provided so as to extend through the first electrodes 31c, 31d, and 31e have been exemplified, but the first recessed portions 31cc, 31dc, and 31eca (31ecb) may be provided so as to be opened to the third electrode 33a side without extending through the first electrodes 31c, 31d, and 31e.

Similarly to the organic EL display device 50 of the first embodiment described above, the organic EL display device of the present embodiment is flexible and is configured to display an image by allowing the light-emitting layer 3 of the organic EL layer 35 to appropriately emit light through the first TFT 9a and the second TFT 9b in each of the subpixels P.

The organic EL display device of the present embodiment can be manufactured by changing the pattern shape in patterning the first electrode 31a in the organic EL element layer formation in the method of manufacturing the organic EL display device 50 of the first embodiment described above.

As described above, according to the organic EL display device of the present embodiment, each first electrode 31c exposed from the first edge cover 32 is provided with the plurality of first recessed portions 31cc extending through the first electrode 31c and exposing the flattening film 20 of the TFT layer 30, and the plurality of first recessed portions 31cc are provided extending to each other in the linear shapes. The surface of each third electrode 33a is provided with the plurality of second recessed portions 33ac corresponding to the plurality of first recessed portions 31cc. Here, each of the solute components of the organic EL layer 35, which is formed on the surface of each third electrode 33a by application and drying and which is generally likely to flow to the periphery due to a coffee ring effect, is less likely to flow to the periphery due to an increase in surface area by the plurality of second recessed portions 33ac formed on the surface of each third electrode 33a. This reduces a difference in film thickness of the organic EL layer 35 formed on the surface of each third electrode 33a by application and drying, thereby suppressing a variation in film thickness of the organic EL layer 35 in the subpixel P. Furthermore, since the variation in film thickness of the organic EL layer 35 in each subpixel P can be suppressed, luminous unevenness due to the organic EL element 39 of the subpixel P can be suppressed, which makes it is possible to suppress a decrease in luminous efficiency.

In addition, according to the organic EL display device of the present embodiment, the plurality of second recessed portions 33ac are provided at the surface of the third electrode 33a having light reflectivity, resulting in the improvement of the brightness when the organic EL layer 35 emits light in each subpixel P.

In addition, according to the organic EL display device of the present embodiment, the line widths of the plurality of first recessed portions 31cc provided in each first electrode 31c exposed from the first edge cover 32 gradually increase from the central portion toward the outside on the inner side of the inner peripheral edge of the first edge cover 32. This increases the surface areas of the plurality of second recessed portions 33ac formed at the surface of each third electrode 33a are increased more at the central portion on the inner side the inner peripheral edge of the first edge cover 32, so that each of the solute components of the organic EL layer 35, which is generally likely to flow to the periphery due to a coffee ring effect, is more unlikely to flow to the periphery. Thus, the variation in film thickness of the organic EL layer 35 can be further suppressed in the subpixel P.

### Third Embodiment

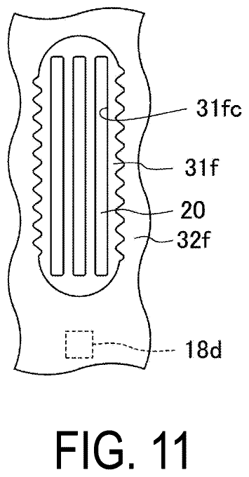

FIG. 11 illustrates a third embodiment of the display device according to the present invention. Here, FIG. 11 is a plan view of a first electrode 31f exposed from a first edge cover 32f constituting an organic EL display device of the present embodiment.

In the respective embodiments, the organic EL display device (50) including the first edge cover 32 whose inner peripheral edge is formed in a track shape has been exemplified. However, in the present embodiment, the organic EL display device including the first edge cover 32f whose inner peripheral edge is partially provided in an uneven shape in a plan view will be exemplified. Here, the track shape means a shape of a track in an athletics stadium, and is constituted by a pair of linear portions facing each other and a pair of semi-circular portions connected to both ends of the pair of linear portions.

The organic EL display device of the present embodiment has substantially the same configuration as that of the organic EL display device 50 except that the first edge cover 32f is used instead of the first edge cover 32 in the organic EL display device 50 of the first embodiment, and thus, a configuration of the first edge cover 32f will be mainly described below. Note that the first electrode 31f is substantially the same as the first electrode 31a in the organic EL display device 50 of the first embodiment, and the first electrode 31f exposed from the first edge cover 32f, is provided with, similarly to the first electrode 31a, a plurality of first recessed portions 31fc extending through the first electrode 31f and exposing the flattening film 20 of the TFT layer 30. The plurality of first recessed portions 31fc extend in linear shapes so as to be in parallel to each other.

The first edge cover 32f is provided in a lattice pattern over an entire display region D so as to cover a peripheral edge portion of each first electrode 31f. Here, the first edge cover 32f is made of, for example, an organic resin material such as a polyimide resin or an acrylic resin, a polysiloxane-based SOG material, or the like. Further, as illustrated in FIG. 11, the inner peripheral edge of the first edge cover 32f is provided in a substantially track shape, and a pair of linear portions facing each other and corresponding to the linear portions of the track are provided in uneven shapes in a plan view. Note that, in the present embodiment, the configuration in which the inner peripheral edge of the first edge cover 32f is partially provided in the uneven shapes in a plan view has been exemplified, but the entire inner peripheral edge of the first edge cover 32f may be provided in the uneven shapes in a plan view.

Similarly to the organic EL display device 50 of the first embodiment described above, the organic EL display device of the present embodiment is flexible and is configured to display an image by allowing the light-emitting layer 3 of the organic EL layer 35 to appropriately emit light through the first TFT 9a and the second TFT 9b in each of the subpixels P.

The organic EL display device of the present embodiment can be manufactured by changing the pattern shape in patterning the first edge cover 32 in the organic EL element layer formation in the method of manufacturing the organic EL display device 50 of the first embodiment.

As described above, according to the organic EL display device of the present embodiment, each first electrode 31f exposed from the first edge cover 32f is provided with the plurality of first recessed portions 31fc extending through the first electrode 31f and exposing the flattening film 20 of the TFT layer 30, and the plurality of first recessed portions 31fc extend to each other in the linear shapes. Further, the surface of each third electrode 33a is provided with the plurality of second recessed portions 33ac corresponding to the plurality of first recessed portions 31fc. Here, each of the solute components of the organic EL layer 35, which is formed on the surface of each third electrode 33a by application and drying and which is generally likely to flow to the periphery due to a coffee ring effect, is less likely to flow to the periphery due to an increase in surface area by the plurality of second recessed portions 33ac formed on the surface of each third electrode 33a. This reduces a difference in film thickness of the organic EL layer 35 formed on the surface of each third electrode 33a by application and drying, thereby suppressing a variation in film thickness of the organic EL layer 35 in the subpixel P. Furthermore, since the variation in film thickness of the organic EL layer 35 in each subpixel P can be suppressed, luminous unevenness due to the organic EL element 39 of the subpixel P can be suppressed, which makes it is possible to suppress a decrease in luminous efficiency.

In addition, according to the organic EL display device of the present embodiment, the plurality of second recessed portions 33ac are provided at the surface of the third electrode 33a having light reflectivity, resulting in the improvement of the brightness when the organic EL layer 35 emits light in each subpixel P.

In addition, according to the organic EL display device of the present embodiment, since the inner peripheral edge of the first edge cover 32f is at least partially provided in the uneven shapes in a plan view, each of the solute components of the organic EL layer 35, which is generally likely to flow to the periphery due to the coffee ring effect, is dispersed in the uneven shapes of the inner peripheral edge of the first edge cover 32f, resulting in the suppression of luminous unevenness due to the organic EL element 39 of each subpixel P.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

Although the organic EL display device in which the electrode of the TFT connected to the first electrode serves as the drain electrode has been exemplified in each of the embodiments described above, the present invention is also applicable to an organic EL display device in which the electrode of the TFT connected to the first electrode is referred to as the source electrode.

In each of the embodiments described above, the organic EL display device has been exemplified as the display device. The present invention can also be applied to a display device including a plurality of light-emitting elements to be driven by a current, for example, to a display device including quantum dot light-emitting diodes (QLEDs), each of which is a light-emitting element using a quantum dot-containing layer.

### INDUSTRIAL APPLICABILITY

As described above, the present invention is useful for a flexible display device.

### REFERENCE SIGNS LIST

D Display region
P Subpixel
10 Resin substrate (base substrate)
20 Flattening film
30 TFT layer (thin film transistor layer)
31a, 31b, 31c, 31d, 31e, 31f First electrode
31ac, 31bc, 31cc, 31dc, 31eca, 31fc First recessed portion
31ecb First recessed portion (of another type)
32, 32f First edge cover
33a Third electrode
33ac Second recessed portion
34 Second edge cover
35 Organic EL layer (organic electroluminescence layer, light-emitting function layer)
36 Second electrode
40 Organic EL element layer (light-emitting element layer)
45 Sealing film
50 Organic EL display device

1. A display device comprising:
a base substrate;
a thin film transistor layer provided on the base substrate; and
a light-emitting element layer provided on the thin film transistor layer, the light-emitting element layer being obtained by layering a plurality of first electrodes, a first edge cover commonly provided, a plurality of light-emitting function layers, and a second electrode commonly provided in order corresponding to a plurality of subpixels constituting a display region,
wherein the first edge cover covers a peripheral edge portion of each of the plurality of first electrodes,
a plurality of third electrodes are provided between the first edge cover and the plurality of light-emitting function layers, and correspond to the plurality of subpixels,
each of the plurality of first electrodes exposed from the first edge cover is provided with a first recessed portion, and
a surface of each of the plurality of third electrodes is provided with a second recessed portion corresponding to the first recessed portion.

2. The display device according to claim 1,
wherein the first recessed portion extends through the corresponding first electrode, among the plurality of first electrodes.

3. The display device according to claim 2,
wherein the thin film transistor layer includes a flattening film provided on a side of the light-emitting element layer, and
the first recessed portion exposes the flattening film.

4. The display device according to claim 1,
wherein a second edge cover commonly provided corresponding to the plurality of subpixels is provided between the plurality of third electrodes and the plurality of light-emitting function layers, and
the second edge cover covers a peripheral edge portion of each of the third electrodes.

5. The display device according to claim 1,
wherein a plurality of the first recessed portions are provided, the plurality of the first recessed portions extending in linear shapes in parallel to each other.

6. The display device according to claim 5,
wherein line widths of the plurality of the first recessed portions gradually increase from a central portion toward an outside on an inner side of an inner peripheral edge of the first edge cover.

7. The display device according to claim 5,
wherein between the plurality of the first recessed portions, a plurality of first recessed portions of another type separated from each other are provided in dot shapes.

8. The display device according to claim 1,
wherein a plurality of the first recessed portions separated from each other are provided in dot shapes.

9. The display device according to claim 8,
wherein areas of the plurality of the first recessed portions gradually increase from a central portion toward an outside on an inner side of an inner peripheral edge of the first edge cover.

10. The display device according to claim 1,
wherein an inner peripheral edge of the first edge cover is at least partially provided in an uneven shape in a plan view.

11. The display device according to claim 1,
wherein each of the plurality of first electrodes and the second electrode has optical transparency, and
each of the third electrodes has light reflectivity.

12. The display device according to claim 1, the display device further comprising:
a sealing film provided on the light-emitting element layer.

13. The display device according to claim 1,
wherein each of the plurality of light-emitting function layers is an organic electroluminescence layer.
